(19) United States
(12) Patent Application Publication
(10) Pub. No.: US 2012/0043567 A1
(43) Pub. Date: Feb. 23, 2012

(54) LED STRUCTURE WITH BRAGG FILM AND METAL LAYER

(76) Inventors: Liang-Jyi YAN, Taipei County (TW); Yea-Chen LEE, Hsinchu County (TW)

(21) Appl. No.: 12/858,889

(22) Filed: Aug. 18, 2010

(51) Int. Cl. H01L 33/10

(52) U.S. Cl. 257/98; 257/E33.026

(57) ABSTRACT

The present invention discloses an LED structure with a Bragg film and a metal layer, wherein a Bragg film and a metal layer are coated on a bottom of a sapphire substrate. The Bragg film includes two optical layers having different refractive indexes and alternately stacked. The materials and thickness of the optical layers of the Bragg film are optimized to form a high-reflectivity area via optical operation, which can effectively reflect the incident light generated by the light emitting layer from different incident angles. The Bragg film together with the metal layer can reflect the light, which is projected downward, to be emitted from the top or lateral of an LED structure. Therefore, the present invention can greatly increase the light-extraction efficiency of the LED structure.

### FIELD OF THE INVENTION

The present invention relates to an LED structure, particularly to an LED structure with a Bragg film and a metal layer.

### BACKGROUND OF THE INVENTION

Refer to FIG. 1 for a conventional blue light LED (Light Emitting Diode) structure. In the conventional blue light LED structure, an N-type GaN (gallium nitride) layer 2, an activation layer 3 and a P-type GaN layer 4 are sequentially formed on a sapphire substrate 1. Then, an N-type electrode 5 and a P-type electrode 6 are respectively coated on the N-type GaN layer 2 and the P-type GaN layer 4. Thus is formed an LED structure.

In the conventional blue light LED structure, the emitted light is projected nondirectionally. Thus, about half of the light is scattered from the sapphire substrate 1. Such an LED structure has inferior light-extraction efficiency and is less likely to be the light source.

In the conventional LED package structure, a metal layer with high refractive index is coated on the back side of an LED chip to reflect the light, which is originally projected downward, from the front side or lateral side of the LED chip so that the light-extraction efficiency can be increased. Due to the metal layer itself can absorb the light, such the LED structure decreases the light reflection efficiency of the bottom and makes the light-extraction efficiency hard to be effectively increased.

### SUMMARY OF THE INVENTION

The primary objective of the present invention is to provide a high-reflectivity LED structure to increase the brightness of an LED.

To achieve the abovementioned objective, the present invention proposes an LED structure with a Bragg film and a metal layer, which comprises a sapphire substrate, a Bragg film, a light emitting layer and a metal layer. The light emitting layer is formed on the sapphire substrate. The Bragg film is arranged on one side of the sapphire substrate and opposite to the light emitting layer. The Bragg film includes at least two layers which are alternately stacked and have different refractive indexes. The metal layer is arranged on the Bragg film.

The Bragg film and metal layer arranged below the sapphire substrate have very high reflective indexes to function as high-reflectivity areas to reflect the light generated by the light emitting layer. The light projected downward is emitted from the top or lateral of the LED structure. Therefore, the present invention can effectively enhance the light-extraction efficiency.

### BRIEF DESCRIPTION OF THE DRAWINGS

FIG. 1 is a sectional view schematically showing a conventional LED structure;

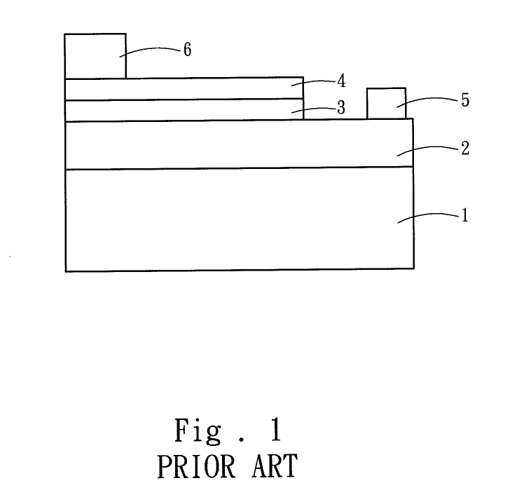

FIG. 2 is a sectional view schematically showing an LED structure according to the present invention;

FIG. 3 is a sectional view schematically showing a Bragg film according to the present invention;

FIG. 4 is a sectional view schematically showing the light emitting condition according to the present invention;

FIG. 5 is a diagram showing the curves of relationships between the wavelength and reflectivity; and

FIG. 6 is a diagram showing the curves of relationships between the incident angle and reflectivity.

### DETAILED DESCRIPTION OF THE PREFERRED EMBODIMENTS

The embodiments are described in detail to demonstrate the technical contents of the present invention. However, it should be understood that the embodiments are only to exemplify the present invention but not to limit the scope of the present invention.

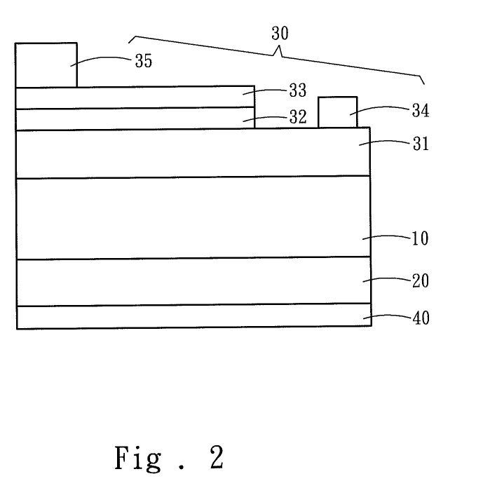

Refer to FIG. 2. The present invention proposes an LED structure with a Bragg film and a metal layer, which comprises a sapphire substrate 10, a Bragg film 20, a light emitting layer 30 and a metal layer 40. The light emitting layer 30 is formed on the sapphire substrate 10. The Bragg film 20 is arranged on one side of the sapphire substrate 10 and opposite to the light emitting layer 30. The metal layer 40 is arranged on the Bragg film 20.

The light emitting layer 30 further comprises an N-type semiconductor layer 31, an activation layer 32 and a P-type semiconductor layer 33. An N-type electrode 34 and a P-type electrode 35 are respectively coated on the N-type semiconductor layer 31 and the P-type semiconductor layer 33. The N-type semiconductor layer 31 and the P-type semiconductor layer 33 are respectively made of a material selected from a group consisting of gallium nitride (GaN), indium gallium nitride (InGaN), aluminum indium gallium nitride (AlInGaN), gallium phosphide (GaP), aluminum indium gallium phosphide (AlInGaP), aluminum indium phosphide (AlInP), and aluminum gallium arsenide (AlGaAs). The activation layer 32 is a periodical structure formed of quantum wells and barrier layers. The quantum well is made of a material selected from a group consisting of gallium nitride (GaN), indium gallium nitride (InGaN), aluminum indium gallium nitride (AlInGaN), gallium phosphide (GaP), aluminum indium gallium phosphide (AlInGaP), aluminum indium phosphide (AlInP), and aluminum gallium arsenide (AlGaAs).

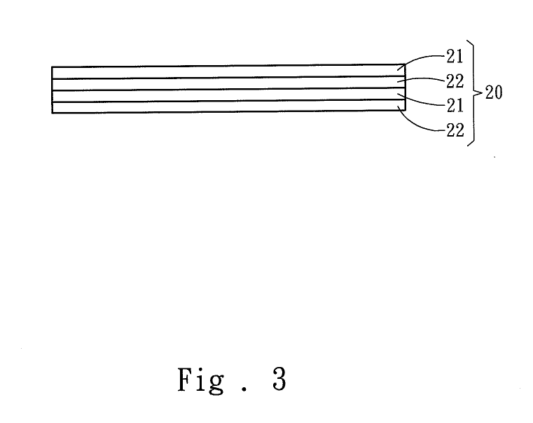

Refer to FIG. 3. The Bragg film 20 includes at least two layers 21 and 22, which are alternately stacked and made of materials having different refractive indexes. In other words, the Bragg film 20 is a multi-layer structure. In FIG. 3, a four-layer structure is used to exemplify the Bragg film 20. The layer 21 with high refractive index is made of a material having a refractive index greater than 1.7, such as titanium dioxide (TiO2), silicon nitride (SiNx), tantalum pentoxide (Ta₂O₅) or zirconium oxide (Zr₂O₃). The layer 22 with low refractive index is made of a material having a refractive index smaller than 1.7, such as silicon dioxide (SiO₂) or magnesium fluoride (MgF₂). The metal layer 40 is made of aluminum or silver.

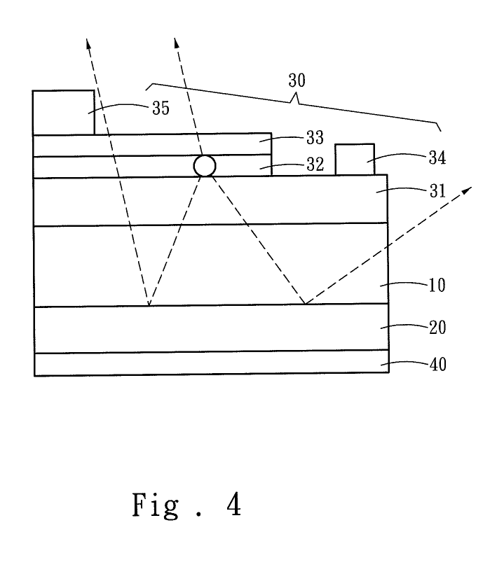

Refer to FIG. 4 for the light emitting condition according to the present invention. The Bragg film 20 is made of two different materials which are alternately stacked and have different refractive indexes. Thus the Bragg film 20 and the metal layer 40 can function as high-reflectivity areas to reflect the light generated by the light emitting layer 30. The light projected downward is emitted from the top or lateral of the LED structure so that the light-extraction efficiency can be increased.

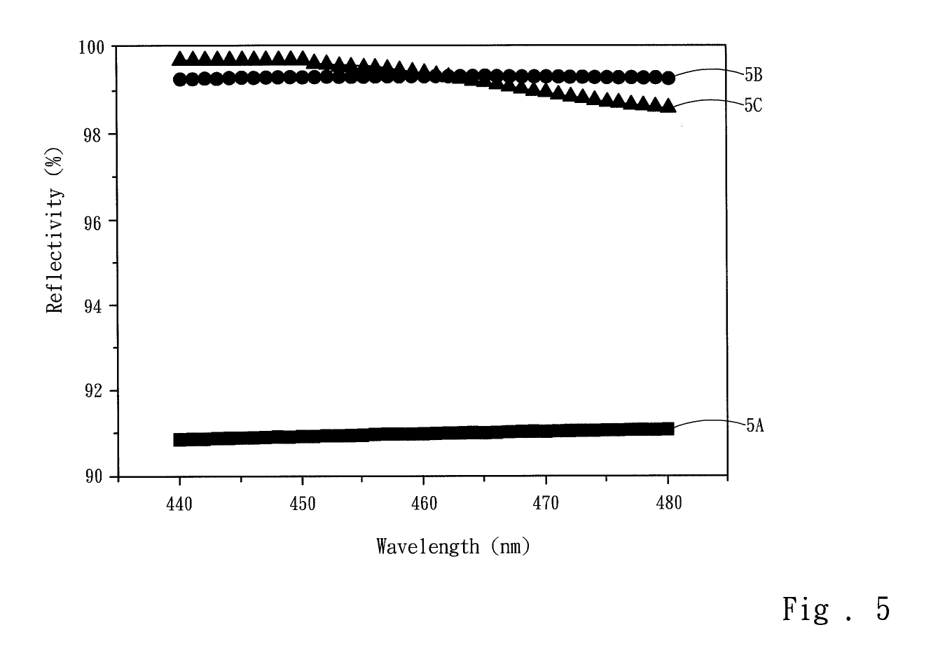

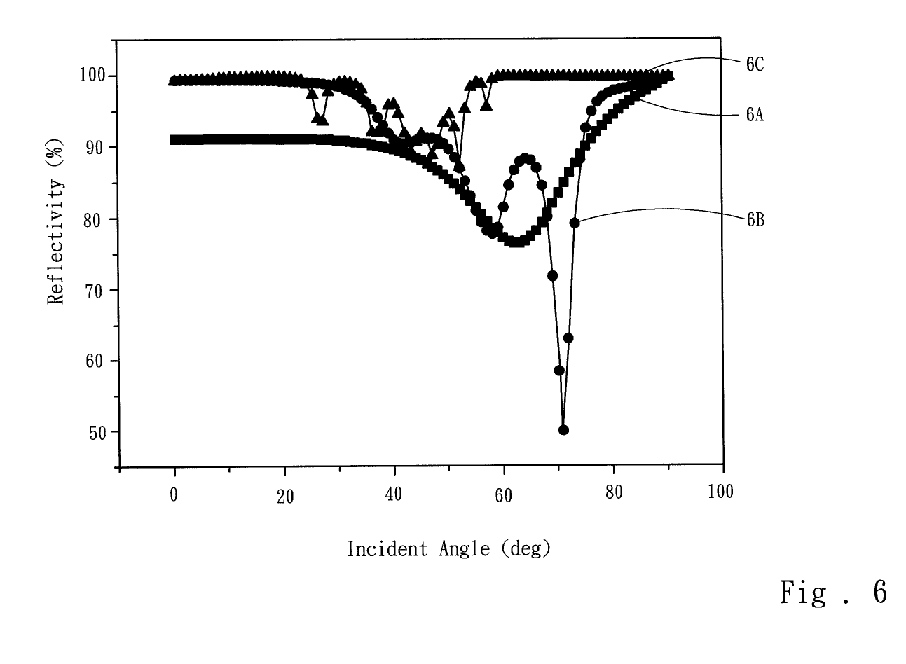

Refer to FIG. 5 and FIG. 6. The Bragg film 20 can be optimized to have optimized thickness and materials stacked by computer simulation software similar to a Bragg reflector. The conventional Bragg reflector is made of two dielectric layers having two different materials alternately stacked, wherein the optical thicknesses of the two materials are identical during stacking. The periodical and alternately-stacked structure is called a Bragg reflector set. The optimized Bragg film 20 includes at least one Bragg reflector set, wherein the optical thicknesses of different layers in the Bragg reflector set are different. After the optimized Bragg film 20 is coated, a metal layer 40 made of aluminum or silver is then coated on the Bragg film 20. Thereby, the high-reflectivity characteristic is provided for various incident angles.

In one embodiment, the optimized Bragg film 20 has a structure sequentially containing layers made of different materials and having different thicknesses: a first layer: SiO₂, λ/(4n); a second layer: TiO₂, λ/(4n); a third layer: SiO₂, λ/(4n); a fourth layer: TiO₂, λ/(4n); a fifth layer: SiO₂, 5λ/(4n); a sixth layer: TiO₂, 3λ/(4n); a seventh layer: SiO₂, 2.41λ/(4n); an eighth layer: TiO₂, 1.2λ/(4n); a ninth layer: SiO₂, 2.43λ/(4n); and a tenth layer: TiO₂, 0.5λ/(4n), wherein λ is the wavelength of the incident light, and n is a positive integer.

Refer to FIG. 5. The light vertically projects to the LED structure downward. Curve 5A is a traditional reflectivity curve using aluminum. Curve 5B is a reflectivity curve using the Bragg film 20 and the metal (aluminum) layer 40 of the present invention. Curve 5C is a reflectivity curve using the optimized Bragg film 20 and metal (aluminum) layer 40 of the present invention. From FIG. 5, it is known that the Curve 5B and Curve 5C are obviously higher than the traditional Curve 5A. Therefore, it is proved that the present invention can increase reflectivity and increase light-extraction efficiency.

Refer to FIG. 6. Curve 6A is a traditional reflectivity curve having a wavelength of 460 nm using aluminum for different incident angles. Curve 6B is a reflectivity curve using the Bragg film 20 and the metal (aluminum) layer 40 of the present invention. Curve 6C is a reflectivity curve using the optimized Bragg film 20 and metal (aluminum) layer 40 of the present invention. From FIG. 6, it is known that the LED using the optimized Bragg film 20 has better reflectivity for different incident angles. Therefore, the present invention can greatly increase the light-extraction efficiency.

What is claimed is:

1. A light emitting diode structure with a Bragg film and a metal layer, comprising:
a sapphire substrate;
a light emitting layer formed on the sapphire substrate;
a Bragg film arranged on one side of the sapphire substrate and opposite to the light emitting layer, and including at least two layers made of two different materials which are alternately stacked and have different refractive indexes; and
a metal layer arranged on the Bragg film.

2. The light emitting diode structure with a Bragg film and a metal layer according to claim 1, wherein the light emitting layer further comprises an N-type semiconductor layer, an activation layer and a P-type semiconductor layer.

3. The light emitting diode structure with a Bragg film and a metal layer according to claim 2, wherein the N-type semiconductor layer and the P-type semiconductor layer are respectively coated an N-type electrode and a P-type electrode.

4. The light emitting diode structure with a Bragg film and a metal layer according to claim 2, wherein the N-type semiconductor layer and the P-type semiconductor layer are respectively made of a material selected from a group consisting of gallium nitride (GaN), indium gallium nitride (InGaN), aluminum indium gallium nitride (AlInGaN), gallium phosphide (GaP), aluminum indium gallium phosphide (AlInGaP), aluminum indium phosphide (AlInP), and aluminum gallium arsenide (AlGaAs).

5. The light emitting diode structure with a Bragg film and a metal layer according to claim 2, wherein the activation layer is a periodical structure formed of quantum wells and barrier layers, and each of the quantum wells is made of a material selected from a group consisting of gallium nitride (GaN), indium gallium nitride (InGaN), aluminum indium gallium nitride (AlInGaN), gallium phosphide (GaP), aluminum indium gallium phosphide (AlInGaP), aluminum indium phosphide (AlInP), and aluminum gallium arsenide (AlGaAs).

6. The light emitting diode structure with a Bragg film and a metal layer according to claim 1, wherein the layer with the high refractive index of the Bragg film has the refractive index greater than 1.7, and another layer with the low refractive index of the Bragg film has the refractive index smaller than 1.7.

7. The light emitting diode structure with a Bragg film and a metal layer according to claim 6, wherein the layer with the high refractive index is made of a material selected from a group consisting of titanium dioxide (TiO₂), silicon nitride (SiNₓ), tantalum pentoxide (Ta₂O₅), and zirconium oxide (Zr₂O₃).

8. The light emitting diode structure with a Bragg film and a metal layer according to claim 6, wherein the layer with the low refractive index is made of a material selected from a group consisting of silicon dioxide (SiO₂) and magnesium fluoride (MgF₂).

9. The light emitting diode structure with a Bragg film and a metal layer according to claim 1, wherein the metal layer is made of aluminum or silver.

10. The light emitting diode structure with a Bragg film and a metal layer according to claim 1, wherein the Bragg film is optimized to have a structure sequentially including layers made of different materials and having different thicknesses: a first layer: SiO₂, λ/(4n); a second layer: TiO₂, λ/(4n); a third layer: SiO₂, λ/(4n); a fourth layer: TiO₂, λ/(4n); a fifth layer: SiO₂, 5λ/(4n); a sixth layer: TiO₂, 3λ/(4n); a seventh layer: SiO₂, 2.41λ/(4n); an eighth layer: TiO₂, 1.2λ/(4n); a ninth layer: SiO₂, 2.43λ/(4n); and a tenth layer: TiO₂, 0.5λ/(4n), wherein λ is a wavelength of incident light, and n is a positive integer.
